(19) United States
(12) Patent Application Publication
(10) Pub. No.: US 2025/0383606 A1
(43) Pub. Date: Dec. 18, 2025

(54) PROJECTION SYSTEM CONTROL

(71) Applicant: ASML Netherlands B.V., Veldhoven (NL)

(72) Inventors: Johan Gertrudis Cornelis KUNNEN, Weert (NL); Cornelis Melchior BROUWER, Veldhoven (NL); Pavel SMAL, Eindhoven (NL); Bram Paul Theodoor VAN GOCH, Maarheeze (NL)

(73) Assignee: ASML Netherlands B.V., Veldhoven (NL)

(21) Appl. No.: 18/876,559

(22) PCT Filed: Nov. 30, 2023
(86) PCT No.: PCT/EP2023/083818

§ 371 Date: Dec. 18, 2024

(30) Foreign Application Priority Data
Dec. 15, 2022 (EP) 22213847.1

(51) Int. Cl. G03F 7/00; G03F 7/20

(52) U.S. Cl. CPC G03F 7/70258; G03F 7/2022; G03F 7/70466; G03F 7/70516; G03F 7/70533; G03F 7/7085

(57) ABSTRACT

A method of controlling a projection system during exposure of a substrate by a lithographic apparatus, the method comprising obtaining a measurement signal of a change of a differential pressure across one or more lenses of a projection system of the lithographic apparatus, calculating an imaging error caused by movement of one or more lens elements of the projection system due to the change of measured differential pressure during the exposure, calculating lens element adjustments which compensate for the calculated imaging error, applying the lens element adjustments, identifying which exposure areas of the substrate were exposed during a delay between the change of differential pressure occurring and the lens element adjustments being applied, and storing information of the identified exposure areas together with the calculated imaging error.

### CROSS-REFERENCE TO RELATED APPLICATIONS

This application claims priority of EP application 22213847.1 which was filed on 15 Dec. 2022, and which is incorporated herein in its entirety by reference.

### FIELD

The present invention relates to method of controlling a projection system of a lithographic apparatus and to an apparatus configured to control a projection system using the method. The method may form part of a lithographic method, and the apparatus may form part of a lithographic apparatus.

### BACKGROUND

A lithographic apparatus is a machine that applies a desired pattern onto a target portion of a substrate. Lithographic apparatus can be used, for example, in the manufacture of integrated circuits (ICs). In that circumstance, a patterning device, which is alternatively referred to as a mask or a reticle, may be used to generate a circuit pattern corresponding to an individual layer of the IC, and this pattern can be imaged onto a target portion (e.g. comprising part of, one or several dies) on a substrate (e.g., a silicon wafer) that has a layer of radiation-sensitive material (resist). In general, a single substrate will contain a network of adjacent target portions that are successively exposed. Known lithographic apparatus include so-called steppers, in which each target portion is irradiated by exposing an entire pattern onto the target portion in one go, and so-called scanners, in which each target portion is irradiated by scanning the pattern through the beam in a given direction (the “scanning”-direction) while synchronously scanning the substrate parallel or anti parallel to this direction.

A problem that may arise is that the lithographic apparatus is affected by the environment in which the lithographic apparatus is provided. For example, when there is a pressure change in a room in which the lithographic apparatus is operating, this may have a detrimental effect upon the accuracy with which the lithographic apparatus projects a pattern onto a substrate.

It is desirable to provide, for example, a method which obviates or mitigates one or more of the problems of the prior art, whether identified herein or elsewhere.

### SUMMARY

According to a first aspect of the present invention, there is provided a method of controlling a projection system during exposure of a substrate by a lithographic apparatus, the method comprising obtaining a measurement signal of a change (or indicating or representing a change) of a differential pressure across one or more lenses of a projection system of the lithographic apparatus, calculating an imaging error caused by movement of one or more lens elements of the projection system due to the change of differential pressure, calculating lens element adjustments which compensate for the calculated imaging error, applying the lens element adjustments, determining which exposure areas of the substrate were exposed during a delay between the change of differential pressure occurring and the lens element adjustments being applied, and storing information identifying those exposure areas together with the calculated imaging error.

Advantageously, because the exposure area imaging errors are stored, subsequent exposures of those exposure areas may take the imaging errors into account. For example, an imaging fingerprint for an exposure area may be replicated for a subsequent exposure of the exposure area.

The method may further comprise, during a subsequent exposure of the identified exposure areas of the substrate, applying lens element adjustments which apply an (second) imaging error based on the calculated imaging error during exposure of the identified exposure areas.

The (second) imaging error that is applied during the subsequent exposure may correspond with the calculated imaging error to compensate therefore.

A time duration of the delay between the change of differential pressure occurring and the lens element adjustments being applied may be determined. The determination may take into account a time duration between the change of differential pressure occurring and the measurement of the change of differential pressure being obtained.

A time duration of the delay between the change of differential pressure occurring and the lens element adjustments being applied may be determined. The determination may take into account a time duration during which the lens element adjustments are calculated.

The measured differential pressure may be between a pressure below a last lens element of the projection system and a pressure between a penultimate lens element and/or a preceding lens element of the projection system.

The differential pressure may be measured by one or more differential pressure sensors.

More than one measured differential pressure may be used. Thus, the obtained measurement signal may comprise or represent one or more differential pressures measured by one or more pressure sensors.

Determining the time duration of the delay between the change of differential pressure occurring and the lens element adjustments being applied may take place during a calibration performed before exposure of the substrate has commenced.

There may be up to ten identified exposure areas. There may be up to six identified exposure areas. There may be up to three identified exposure areas.

According to a second aspect of the invention there is provided a lithographic apparatus comprising a substrate support (or substrate table) configured to support or hold a substrate, and a projection system configured to project a patterned radiation beam from a patterning device onto a substrate, the projection system comprising a plurality of lens elements, one or more pressure sensors configured to obtain a differential pressure measurement across one or more lenses of the projection system, a controller configured to calculate an imaging error caused by movement of one or more lens elements of the projection system due to a change of differential pressure occurring, the controller further being configured to calculate lens element adjustments which compensate for the calculated imaging error, and lens element adjusters configured to receive and apply the lens element adjustments, wherein the controller is further configured to determine and identify which exposure areas of the substrate were exposed during a delay between the change of differential pressure occurring and the lens element adjustments being applied, and to store information identifying those exposure areas together with the calculated imaging error.

Advantageously, because the exposure area imaging errors are stored, subsequent exposures of those exposure areas may take the imaging errors into account. For example, an imaging fingerprint for an exposure area may be replicated for a subsequent exposure of the exposure area.

The controller may be further configured to, during a subsequent exposure of the substrate, apply lens element adjustments which apply an (second) imaging error based on the calculated imaging error during exposure of the identified exposure areas.

The imaging error that is applied during the subsequent exposure may correspond with corresponds with the calculated imaging error.

The apparatus may comprise at least one differential pressure sensor.

The projection system may comprise a plurality of differential pressure sensors.

The differential pressure measurement may be between a pressure below a last lens element of the projection system and a pressure between a penultimate lens element and/or a preceding lens element of the projection system.

One or more pressure sensors may be arranged at a space or volume at the last lens element of the projection lens, at a space or volume at the penultimate lens, and or at a space or volume at the preceding lens of the projection lens.

The controller may be configured to identify up to ten exposure areas. The controller may be configured to identify up to six exposure areas. The controller may be configured to identify up to three exposure areas.

Features of different aspects of the invention may be combined together.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 depicts a projection system and controller according to an embodiment of the invention;

FIG. 3 shows a method according to an embodiment of the invention; and

FIG. 4 is a graph that illustrates operation of an embodiment of the invention.

### DETAILED DESCRIPTION

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, liquid-crystal displays (LCDs), thin film magnetic heads, etc. The skilled artisan will appreciate that, in the context of such alternative applications, any use of the terms “wafer” or “die” herein may be considered as synonymous with the more general terms “substrate” or “target portion”, respectively. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g., having a wavelength of 365, 248, 193, 157 or 126 nm).

The term “patterning device” used herein should be broadly interpreted as referring to a device that can be used to impart a radiation beam with a pattern in its cross-section such as to create a pattern in a target portion of the substrate. It should be noted that the pattern imparted to the radiation beam may not exactly correspond to the desired pattern in the target portion of the substrate. Generally, the pattern imparted to the radiation beam will correspond to a particular functional layer in a device being created in the target portion, such as an integrated circuit.

A patterning device may be transmissive or reflective. Examples of patterning device include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions; in this manner, the reflected beam is patterned.

The support structure holds the patterning device. It holds the patterning device in a way depending on the orientation of the patterning device, the design of the lithographic apparatus, and other conditions, such as for example whether or not the patterning device is held in a vacuum environment. The support can use mechanical clamping, vacuum, or other clamping techniques, for example electrostatic clamping under vacuum conditions. The support structure may be a frame or a table, for example, which may be fixed or movable as required and which may ensure that the patterning device is at a desired position, for example with respect to the projection system. Any use of the terms “reticle” or “mask” herein may be considered synonymous with the more general term “patterning device”.

The term “projection system” used herein should be broadly interpreted as encompassing various types of projection system, including refractive optical systems, reflective optical systems, and catadioptric optical systems, as appropriate for example for the exposure radiation being used, or for other factors such as the use of an immersion fluid. Any use of the term “projection lens” herein may be considered as synonymous with the more general term “projection system”.

The illumination system may also encompass various types of optical components, including refractive, reflective, and catadioptric optical components for directing, shaping, or controlling the beam of radiation, and such components may also be referred to below, collectively or singularly, as a “lens”.

The lithographic apparatus may be of a type having two (dual stage) or more substrate tables (and/or two or more support structures). In such “multiple stage” machines the additional tables may be used in parallel, or preparatory steps may be carried out on one or more tables while one or more other tables are being used for exposure.

The lithographic apparatus may also be of a type wherein the substrate is immersed in a liquid having a relatively high refractive index, e.g., water, so as to fill a space between the final element of the projection system and the substrate. Immersion techniques are well known in the art for increasing the numerical aperture of projection systems.

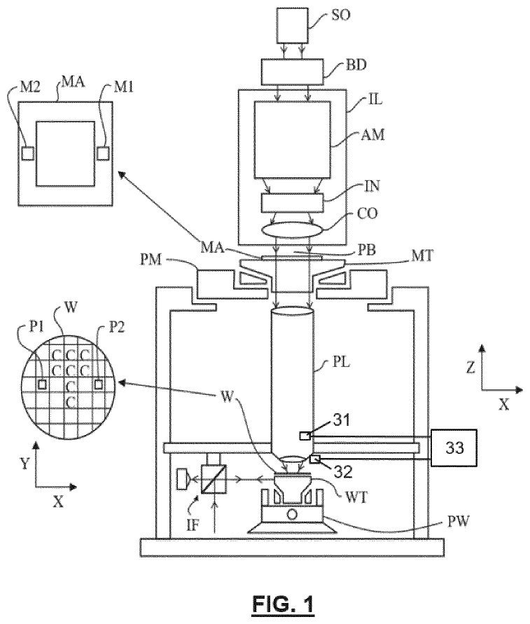

FIG. 1 schematically depicts a lithographic apparatus according to a particular embodiment of the invention. The apparatus comprises: an illumination system (illuminator) IL to condition a beam PB of radiation (e.g., UV radiation or DUV radiation), a support structure (e.g., a mask table) MT to support a patterning device (e.g., a mask) MA and connected to first positioning device PM to accurately position the patterning device with respect to item PL, a substrate table (e.g., a wafer table) WT for holding a substrate (e.g., a resist coated wafer) W and connected to second positioning device PW for accurately positioning the substrate with respect to item PL, and a projection system (e.g., a refractive projection lens) PL configured to image a pattern imparted to the radiation beam PB by patterning device MA onto a target portion C (e.g., comprising one or more dies) of the substrate W.

As here depicted, the apparatus is of a transmissive type (e.g., employing a transmissive mask). Alternatively, the apparatus may be of an at least partially reflective type (e.g., employing a reflective mask or programmable mirror array of a type as referred to above).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases the source may be integral part of the apparatus, for example when the source is a mercury lamp. The source SO and the illuminator IL, together with the beam delivery system BD if required, may be referred to as a radiation system.

The illuminator IL may comprise adjusting means AM for adjusting the angular intensity distribution of the beam. Generally, at least the outer and/or inner radial extent (commonly referred to as σ-outer and σ-inner, respectively) of the intensity distribution in a pupil plane of the illuminator can be adjusted. In addition, the illuminator IL generally comprises various other components, such as an integrator IN and a condenser CO. The illuminator provides a conditioned beam of radiation PB, having a desired uniformity and intensity distribution in its cross section.

The radiation beam PB is incident on the patterning device (e.g., mask) MA, which is held on the support structure (e.g., reticle or mask table) MT. Having traversed the patterning device MA, the beam PB passes through the projection system PL, which focuses the beam onto a target portion C of the substrate W. With the aid of the second positioning device PW and position sensor IF (e.g., an interferometric device), the substrate table WT can be moved accurately, e.g., so as to position different target portions C in the path of the beam PB. Similarly, the first positioning device PM and another position sensor (which is not explicitly depicted in FIG. 1) can be used to accurately position the patterning device MA with respect to the path of the beam PB, e.g., after mechanical retrieval from a mask library, or during a scan. In general, movement of the object tables MT and WT will be realized with the aid of a long-stroke module (coarse positioning) and a short-stroke module (fine positioning), which form part of the positioning device PM and PW. However, in the case of a stepper (as opposed to a scanner) the support structure MT may be connected to a short stroke actuator only, or may be fixed. Patterning device MA and substrate W may be aligned using patterning device alignment marks M1, M2 and substrate alignment marks P1, P2.

The lithographic apparatus further comprises a controller 33 which is configured to determine imaging errors of the projection system, and to calculate adjustments to be applied to lens elements of the projection system which compensate for the imaging errors. The lithographic apparatus further comprises first and second pressure sensors 31,32, which are configured to provide pressure measurements to the controller 33.

The depicted apparatus can be used in the following preferred modes:

In step mode, the support structure MT and the substrate table WT are kept essentially stationary, while an entire pattern imparted to the beam PB is projected onto a target portion C in one go (i.e., a single static exposure). The substrate table WT is then shifted in the X and/or Y direction so that a different target portion C can be exposed. In step mode, the maximum size of the exposure field limits the size of the target portion C imaged in a single static exposure.

In scan mode, the support structure MT and the substrate table WT are scanned synchronously while a pattern imparted to the beam PB is projected onto a target portion C (i.e., a single dynamic exposure). The velocity and direction of the substrate table WT relative to the support structure MT is determined by the (de-)magnification and image reversal characteristics of the projection system PL. In scan mode, the maximum size of the exposure field limits the width (in the non-scanning direction) of the target portion in a single dynamic exposure, whereas the length of the scanning motion determines the height (in the scanning direction) of the target portion.

In another mode, the support structure MT is kept essentially stationary holding a programmable patterning device, and the substrate table WT is moved or scanned while a pattern imparted to the beam PB is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

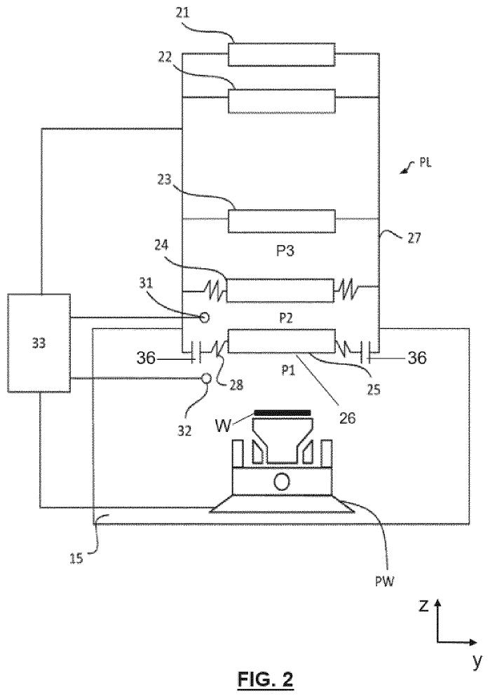

FIG. 2 schematically depicts an example projection system PL in which there is shown first to fifth lens elements 21-25. It will be appreciated that the depiction of five lens elements is merely exemplary and that the projection system PL may comprise any number of lens elements. In FIG. 2, lens element 25 is the “last” lens element, i.e., the lens element closest to the substrate W. A face 26 of the last lens element 25 directly opposes the substrate W. A first pressure P1 prevails in a first volume adjacent the face 26. The first volume may be delimited by a substrate compartment 15 within which the substrate table PW is located, or may be delimited by other components (such as an immersion bath where the lithographic apparatus is an immersion system). The first volume 15 may be referred to as an environment on a bottom side of the last lens element 25.

In an embodiment, the projection system PL is part of an immersion lithographic system in which an immersion bath containing an immersion medium (for example, highly purified water) may be provided between the last lens element 25 and the substrate W in order to increase the numerical aperture and thereby increase the resolution of the lithography apparatus. In such a system, the last lens element 25 may be connected to a housing 27 of the projection system by a permeable (or “leaky”) seal 28 to reduce a pressure gradient over the last lens element 25. In particular, the last lens element 25 may have a higher optical sensitivity and be attached to the housing 27 with a lower stiffness than a penultimate lens element 24, for example.

A positive pressure may be provided by a gas source (not depicted) within the projection system PL. Consequently, there may be a difference between the pressure P1 below the last lens element 25 and the pressure P2 above the last lens element 25. This may be referred to as a differential pressure. The differential pressure may be referred to as DP12. A change of the pressure P1 in the environment 15 below the last lens element 25 may occur. When this happens, it will give rise to a change of differential pressure DP12. The last lens element 25 will move as a result of the differential pressure DP12. For example, if the pressure P1 increases then the last lens element 25 will move towards the penultimate lens element 24 (i.e., upwards in FIG. 2). The movement of the last lens element 25 may comprise a combination of rotation and z-direction (upward or downward) movement. This movement will have a detrimental effect upon the accuracy with which patterns are projected by the lithographic apparatus onto substrates. It may take a few seconds for the change of differential pressure DP12 to decay, due to the effect of the positive pressure provided within the projection system.

There may also be a differential pressure between other lens elements. When a pressure change occurs in the environment 15, it may cause a change of differential pressure for other locations in the projection system PL. For example a change of differential pressure DP13 may occur between the pressure P1 below the last lens element 25 and a pressure P3 between a penultimate lens element 24 and a preceding lens element 23. The depicted embodiment measures the differential pressure DP12. However, other embodiments may measure the differential pressure DP13 (or a different differential pressure).

In the depicted embodiment, a first pressure sensor 31 is located between the last lens element 25 and the penultimate lens element 24. A second pressure sensor 32 is located on an opposite side of the last lens element 25. In other embodiments, the pressure sensors 31, 32 may be provided at other locations. In general the pressure sensors 31, 32 may be located at positions which allow the differential pressure DP12 to be measured (or a different differential pressure). The second pressure sensor 32 may be located elsewhere in the first area (e.g., elsewhere in the substrate compartment 15). The pressure sensors 31, 32 may be any pressure sensors suitable for measuring the pressures P1, P2 (e.g., a conventional digital pressure sensor).

Each pressure sensor 31,32 is connected to the controller 33 and provides a pressure measurement signal to the controller 33. The controller 33 is configured to determine the differential pressure DP12 using the pressure measurements (or pressure measurement signals or representatives thereof).

The measurement signal provided to the controller 33 may comprise or represent one or more differential pressures measured by one or more pressure sensors.

More than one pressure sensor may be provided at a same surface of a lens element 21-25. Herewith, a pressure difference over the surface of the lens element 21-25 can be measured (i.e., differential pressure over a single lens surface, and change thereof). A change in pressure difference over the surface of the lens element 21-25 may cause a tilt or an asymmetric displacement of the lens element. The received or measured change of differential pressure may be a change of differential pressure across a single side of the surface of a lens element (or lens surface). The calculated imaging error may be based on this differential pressure change. A lens correction or adjustment may be applied to correct for this change by means of the controller 33.

In addition, the pressure change across or over the surface of the lens element 21-25 may result in a change in refractive index of the fluid (e.g., a purging gas or an immersion liquid) at the lens element. A change in refractive index may cause an (additional) imaging error. The controller 33 may be arrange to calculate and to correct for this change in refractive index (the induced imaging error). A correction may be applied as a lens element correction/adjustment, by means of the controller 33.

In an alternative arrangement (not depicted), the pressure sensor may be a differential pressure sensor. In such an arrangement, a tube connects one side of the differential pressure sensor to space between the last lens element 25 and the penultimate lens element 24. The other side of the differential pressure sensor is in the environment 15 of the bottom side of the last lens element 25 (i.e., receives the pressure on the opposite side of the last lens element). The two sides of the differential pressure sensor thus receive pressures from either side of the last lens element 25. The differential pressure sensor directly measures the differential pressure DP12. Where this arrangement is used, the controller 33 does not need to determine the differential pressure DP12 using two pressure measurements, but instead directly receives the differential pressure DP12. Directly measuring the differential pressure may be more accurate than measuring two pressures and calculating the differential pressure (because the difference between the pressures may be small compared with the values of the pressures). A plurality of differential pressure sensors may be provided. The differential pressure sensors may be configured to measure different differential pressures (e.g., DP12, DP13, etc.).

The projection system PL may comprise a plurality of differential pressure sensors. Each differential sensor may be arranged to measure a pressure difference over a lens element provided in the projection lens.

Both sides of the differential pressure sensor may be provided at the same space. Herewith, a differential pressure (and a change thereof) across a single surface of a lens element 21-25 can be measured and may be taken into account for calculating the imaging error. In turn, this contribution to the imaging error may be used for the lens adjustments.

In a further alternative arrangement, the differential pressure DP12 may be determined by electronics located before the controller 33 (e.g., using a circuit configured to determine the difference between two pressure measurements).

A change of pressure and/or of differential pressure may occur for example when an operator opens a door of a room in which the lithographic apparatus LA is located. This may happen during exposure of a substrate W by the lithographic apparatus LA. The controller 33 may be configured to calculate an imaging error caused by movement of the last lens element 25 and/or other lens elements due to a change of differential pressure DP12, DP13. The imaging error may comprise overlay and image focus characteristics.

The controller 33 may be further configured to calculate lens element adjustments, which compensate for the imaging error. Signals are then sent to the lens elements 21-25 to cause the adjustments of the lens elements to take place. The adjustments may for example comprise heating or cooling a lens element, heating or cooling an area of a lens element, moving a lens element, etc.

The controller 33 may be further configured to determine which exposure areas of the substrate were exposed during a delay between the change of differential pressure occurring (e.g., due to the room door being opened) and the lens element adjustments being applied. The controller stores information identifying those exposure areas together with the imaging error for those exposure areas. The imaging error for those exposure areas can be taken into account when performing subsequent exposures of those exposure areas. For example, the same (or partially the same) imaging error may be deliberately applied by a lithographic apparatus performing a subsequent exposure of those areas. The imaging error may be referred to as an overlay fingerprint. In general, the imaging error that is applied for a subsequent exposure may be based on the imaging error present during previous exposure of the corresponding exposure area. That is, the imaging error that is applied may correspond with the previously present imaging error or may include some differences. The differences may for example arise from a difference in properties of a pattern that is being exposed, compared with a previously exposed pattern. The imaging error that is applied may correspond with the imaging error present during previous exposure of the corresponding exposure area.

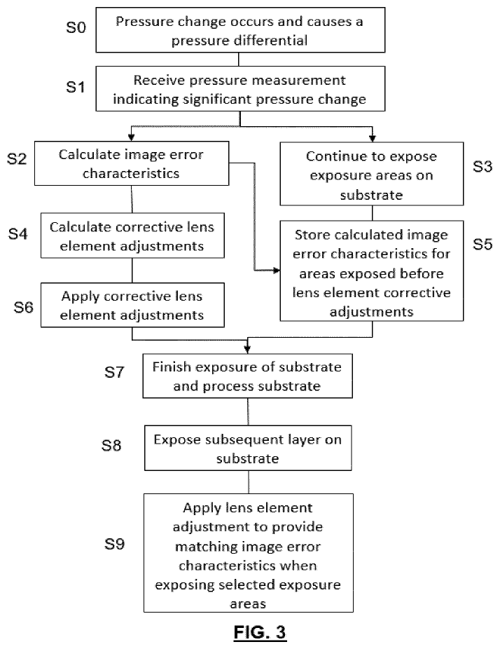

FIG. 3 schematically depicts a method according to an embodiment of the invention. The method is used when a change of pressure differential pressure PD12, DP13 occurs. The change of differential pressure is indicated as step SO.

In a first step S1 of the method, the controller 33 receives a signal of a differential pressure measurement (e.g., receiving signals representative of measurements from the pressure sensors 31, 32). The differential pressure measurement may exceed a threshold value, indicating a significant change of differential pressure DP12, DP13. The change of differential pressure may for example be caused by a door of a room within which the lithographic apparatus LA is provided being opened or closed by an operator. The change of pressure may also have a different cause. Lithographic exposure of a substrate W is underway, and some exposure areas C of a substrate W may already have been exposed. In this document the term “exposure area” is intended to mean an area which is exposed during a single exposure by the lithographic apparatus LA (for example, a single exposure field).

At step S2 the controller 33 calculates imaging error characteristics which are caused by lens deviation due to the change of the differential pressure DP12, DP13. As indicated by step S3, exposure areas continue to be exposed on the substrate W whilst the calculation is taking place.

At step S4 corrective lens element adjustments are calculated. The corrective lens element adjustments adjust imaging characteristics of the projection system PL to compensate for the imaging errors caused by the change of differential pressure. Exposure areas continue to be exposed on the substrate whilst the calculation is taking place.

At step S5 the imaging error characteristics which are calculated at step S2 are stored in a memory. The imaging error characteristics are associated with specific exposure areas of the substrate W.

At step S6 the corrective lens element adjustments that were calculated are applied to the projection system PL, as a result of which imaging errors that were present due to the lens deviation are compensated for (the imaging errors may be substantially removed). Subsequent exposures of the substrate W include correction for the change of differential pressure DP12, DP13.

There may be a significant delay between the change of pressure differential occurring and the corrective lens element adjustments being applied to the projection system PL. The delay may correspond with the time taken to expose a plurality of exposure areas on the substrate W. As an example, there may be a delay which corresponds with the exposure of five exposure areas on the substrate W. Referring again to step S5, the calculated error characteristics are recorded for those five exposure areas (or other plurality of exposure areas).

At step S7, exposure of the substrate W is completed. The substrate W is removed from the lithographic apparatus LA and is processed. Processing may for example comprise one or more of developing photoresist on the substrate, depositing material onto the substrate, chemical mechanical polishing of the substrate, etc.

At step S8 a subsequent layer is exposed on the substrate W. This exposure of the subsequent layer may be performed by the same lithographic apparatus LA as performed the previous exposure, or may be performed by a different lithographic apparatus.

At step S9, during exposure of the subsequent layer on the substrate, a lens adjustment is applied to the projection system PL of the lithographic apparatus LA to introduce an imaging error. The imaging error is applied when exposing exposure areas that correspond to the exposure areas that were previously exposed following the start of the change of differential pressure and before the corrective lens element adjustments were applied. These exposure areas may be referred to as selected exposure areas (or interim exposure areas). For a given selected exposure area, the lens adjustment which is applied generates an imaging error which substantially corresponds with the imaging error present when the previous layer was exposed. This may be referred to by saying that the overlay fingerprint during the exposure is matched to the overlay fingerprint for that exposure area when the previous layer was exposed. Pattern features of the area being exposed are aligned with pattern features that were exposed in the previous layer.

The exposure areas that were exposed following the start of the change of differential pressure and before the corrective lens element adjustments were applied may be referred to as interim exposure areas. There may be a plurality of interim exposure areas. For example, there may be up to ten interim exposure areas. For example there may be up to six exposure areas. There may be up to three exposure areas.

In an embodiment, the method is run continuously. In this embodiment, the imaging error arising from any change of differential pressure DP12, DP13 may be taken into account during exposure of subsequent layers. In an alternative embodiment, the method is triggered to run when the differential pressure changes by more than a threshold value. An advantage of this embodiment is that computation power is only used when a significant error due to a significant change of differential pressure is expected to occur.

In an embodiment, a time period between the change of differential pressure occurring at step S0 and the corrective lens element adjustments being applied at step S6 is measured. The time period may be made up of two components. A first component may be a delay arising from the measurement itself. For example, a period of around a few tenths of a second, for example 0.1 to 0.5 second (or some other period), may elapse between the change of pressure differential occurring and a measurement of the change of differential pressure being received by the controller 33. A second component may be a delay arising from the time needed to calculate the corrective lens adjustments. For example, a period of a few tenths of a second, for example around 0.1 to 0.5 seconds (or some other period), may be needed in order to calculate the corrective lens element adjustments to be applied to the projection system PL.

Using knowledge of the time delay between a change of differential pressure occurring and the measured change being received by the controller 33, and knowledge of the time required to calculate the corrective lens element adjustments, the controller 33 can determine which exposure areas C on a substrate W have suffered from exposure with imaging errors caused by the change of differential pressure. For example, the controller 33 determines that exposure areas exposed from 0.4 seconds before the pressure change in the room was detected will include the imaging error, and exposure areas exposed for 0.4 seconds after the pressure change differential pressure in the room was detected will include the imaging error.

When exposing a subsequent layer, the exposure areas that suffered from the imaging error are identified. Lens element adjustments which provide a corresponding imaging error may be applied when exposing those exposure areas. The lens element adjustments are not applied when exposing other exposure areas.

Corrective lens element adjustments may be applied after an exposure area has been exposed and before the next exposure area is exposed. This provides some time to apply the adjustments between exposures. In an alternative approach, the adjustments may be applied during an exposure.

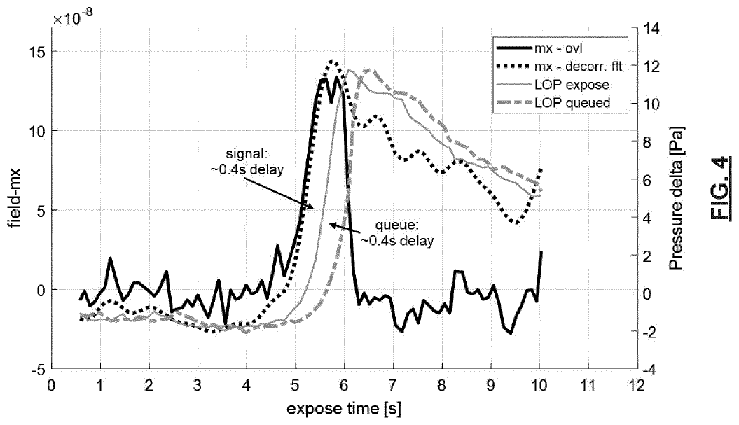

FIG. 4 is a graph which provides an illustration of the operation of an embodiment of the invention. In FIG. 4 the black line (mx-ovl) is a metric which indicates the accuracy with which a pattern is exposed on a substrate. The metric may be referred to as overlay, and is a measurement of the extent to which pattern features are projected at the correct locations on a substrate. The correct locations may correspond with the locations of a previously projected pattern. The left hand scale of the graph indicates the overlay (zero indicating a perfect overlay).

The dotted line (mx-decorr. flt) indicates the differential pressure DP13 from the pressure P1 below the last lens element 25 and the pressure P3 between the penultimate lens element 24 and the preceding lens element 23. The right hand scale of the graph indicates the differential pressure. As may be seen, the differential pressure is initially around 0, and then rises rapidly at around 5 seconds. This change of differential pressure may correspond with for example an operator opening the door of a room in which the lithographic apparatus LA is located. As shown in FIG. 4, the differential pressure decays over time, although it has not reached zero by the end of the depicted period of 10 seconds.

The grey (thinner) line (LOP expose) in FIG. 4 indicates the measured differential pressure DP13 as received by the controller 33. From comparing the dotted line and the grey line it can be seen that there is a delay between the change of differential pressure and the controller 33 receiving a corresponding measured change of differential pressure.

The dashed line (LOP queued) in FIG. 4 shows differential pressure values which correspond with corrective lens element adjustments. These differential pressure values were calculated based upon corrections calculated for the lens elements. There is a direct relationship between the calculated lens element adjustments and the differential pressure values, and this direct relationship allows the differential pressure which corresponds with the lens element adjustments to be plotted in the graph. The differential pressure values are contemporaneous with the corrective lens element adjustments which are applied to the lens elements 21-25. In other words, there is a direct instantaneous relationship between the differential pressure depicted by the dashed line and the corrective lens element adjustments which are applied. As depicted, there is a time delay of around 0.8 seconds between the change of differential pressure and lens element adjustments for the change of differential pressure being applied.

As may be seen from the black line, the corrective lens element adjustments which are applied begin to take effect around 0.8 seconds after the change of differential pressure takes place. The overlay drops to around 0 just after 6 seconds of exposure time. The intersection of the black overlay line with the dashed differential pressure line corresponding to lens element adjustment timing demonstrates the correlation between the overlay correction and the differential pressure values which correspond with that correction.

Although the depicted embodiment has a delay of around 0.8 seconds, a different delay may apply for other embodiments.

In the depicted embodiment in FIG. 2, the differential pressure DP12 on either side of the last lens element 25 of the projection system PL is used. However, in the graph of FIG. 4, the differential pressure DP13 is used, i.e., the difference between the pressure P1 below the last lens element 25 and the pressure P3 between the penultimate lens element 24 and the preceding lens element 23. Using the differential pressure DP13 may be particularly advantageous and may provide a better correction than using the differential pressure DP12. A change of differential pressure DP12 may decay relatively rapidly due to openings 36 which provide some pressure communication to the back of the last lens element 25. A change of differential pressure DP13 may decay less rapidly and thus will continue to cause lens deviation (and hence imaging errors) after the differential pressure DP12 has decayed. Thus, the differential pressure DP13 may correlate more accurately with imaging errors than the differential pressure DP12.

In other embodiments, the differential pressure between other parts of the projection system PL may be used.

The lens element movement in response to a given change of differential pressure may differ for different lens elements, because the stiffness of mechanical connection of the lens elements to their supporting structure may differ.

More than one differential pressure may be used. Using more than one differential pressure may advantageously increase the accuracy of the correction provided by embodiments of the invention. This is because the lens element movement and associated imaging error may be more accurately determined.

The time delay between the pressure changing and lens element adjustments being applied may be measured during a calibration. The calibration may be performed before exposure of the substrate has commenced. The time delay may remain constant for a given lithographic apparatus LA, in which case the time delay may be measured a single time. The time delay may vary slowly, in which case the time delay may be measured periodically with a period appropriate for the rate of variation (e.g., weekly, monthly, etc.). The time delay may change if software calculating the lens element adjustments is changed. In such a case the time delay may be measured when the software has been changed. The calibration may comprise exposing a substrate when a significant pressure change is occurring, e.g., due to opening a door to a room in which the lithographic apparatus is operating. The calibration may comprise performing measurements of the exposed substrate to determine when the pressure change took place, and comparing this with signals received by the controller 33 indicating the pressure change. The calibration may comprise performing measurements of the exposed substrate W to determine a delay between the pressure change taking place and lens adjustments being applied to correct for the effect of the pressure change.

According to a further embodiment of the invention, there is provided a method for controlling a projection system, wherein the projection system comprises lens adjustment means. The method comprises: receiving data of a first pressure in a compartment of the projection system and a second pressure in an environment at the projection system during a first exposure, determining a pressure difference between the first and second pressure, receiving data of lens adjustments based on a change in the pressure difference during the first exposure, calculating a lens position error based on a time delay between the change and the lens adjustments provided by the lens adjustment means, and determining a lens position for a second exposure based on the lens position error during the first exposure.

It will be appreciated by the skilled person that features of different aspects of the invention, as disclosed above, may be combined together.

A method according to an embodiment of the invention may be performed by a computing device. The device may comprise a central processing unit (“CPU”) to which is connected a memory. The method described herein may be implemented in code (software) stored on a memory comprising one or more storage media, and arranged for execution on a processor comprising on or more processing units. The storage media may be integrated into and/or separate from the CPU. The code, which may be referred to as instructions, is configured to be fetched from the memory and executed on the processor to perform operations in line with embodiments discussed herein. Alternatively it is not excluded that some or all of the functionality of the CPU is implemented in dedicated hardware circuitry, or configurable hardware circuitry like an FPGA.

The computing device may comprise an input configured to enable a user to input data into a software program running on the CPU. The input device may comprise a mouse, keyboard, touchscreen, microphone etc. The computing device may further comprises an output device configured to output results of measurements to a user.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Aspects of the invention are set out in the clauses below.

1. A method of controlling a projection system during exposure of a substrate by a lithographic apparatus, the method comprising:
obtaining a measurement signal indicating or representing a change of a differential pressure across one or more lenses of a projection system of the lithographic apparatus;
calculating an imaging error caused by movement of one or more lens elements of the projection system due to the change of differential pressure during exposure;
calculating lens element adjustments which compensate for the calculated imaging error; applying the lens element adjustments;
identifying which exposure areas of the substrate were exposed during a delay between the change of differential pressure occurring and the lens element adjustments being applied; and storing information of identified exposure areas together with the calculated imaging error.
2. The method of clause 1, wherein the method further comprises, during a subsequent exposure of the identified exposure areas of the substrate, applying lens element adjustments which apply an (second) imaging error based on the calculated imaging error during exposure of the identified exposure areas.
3. The method of clause 2, wherein the imaging error that is applied during the subsequent exposure corresponds with the calculated imaging error.
4. The method of any preceding clause, wherein a time duration of the delay between the change of differential pressure occurring and the lens element adjustments being applied is determined, the determination taking into account a time duration between the change of differential pressure occurring and the measurement of the change of differential pressure being obtained.
5. The method of any of clauses 1 to 3, wherein a time duration of the delay between the change of differential pressure occurring and the lens element adjustments being applied is determined, the determination taking into account a time duration during which the lens element adjustments are calculated.
6. The method of any preceding clause, wherein the measured differential pressure is between a pressure below a last lens element of the projection system and a pressure between a penultimate lens element and a preceding lens element of the projection system.
7. The method of any of clauses 1 to 5, wherein the measured differential pressure is between a pressure below a last lens element of the projection system and a pressure above the last lens element of the projection system.
8. The method of any preceding clause, wherein the differential pressure is measured by at least one differential pressure sensor.
9. The method of any preceding clause, wherein more than one measured differential pressure is used.
10. The method of clause 4 or clause 5, wherein determining the time duration of the delay between the change of differential pressure occurring and the lens element adjustments being applied takes place during a calibration performed before exposure of the substrate has commenced.
11. The method of any preceding clause, wherein there are up to ten identified exposure areas.
12. A lithographic apparatus comprising:
a substrate table configured to support a substrate;
a projection system configured to project a patterned radiation beam from a patterning device onto a substrate, the projection system comprising a plurality of lens elements;
one or more pressure sensors configured to obtain a differential pressure measurement across one or more lenses of the projection system;
a controller configured to calculate an imaging error caused by movement of one or more lens elements of the projection system due to a change of differential pressure occurring;
the controller further being configured to calculate lens element adjustments which compensate for the calculated imaging error; and
lens element adjusters configured to receive and apply the lens element adjustments; wherein the controller is further configured to determine or to identify which exposure areas of the substrate were exposed during a delay between the change of differential pressure occurring and the lens element adjustments being applied, and to store information identifying those exposure areas together with the calculated imaging error.
13. The lithographic apparatus of clause 12, wherein the controller is further configured to, during a subsequent exposure of the substrate, apply lens element adjustments which apply an (second) imaging error based on the calculated imaging error during exposure of the identified exposure areas.
14. The lithographic apparatus of clause 13, wherein the imaging error that is applied during the subsequent exposure corresponds with calculated imaging error.
15. The lithographic apparatus of any of clauses 12 to 14, wherein the apparatus comprises at least one differential pressure sensor arranged to measure a pressure difference over at least one lens element.
16. The lithographic apparatus of clause 15, wherein the projection system comprises a plurality of differential pressure sensors.
17. The lithographic apparatus of any of clauses 12 to 16, wherein the differential pressure measurement is between a pressure below a last lens element of the projection system and a pressure between a penultimate lens element and a preceding lens element of the projection system.
18. The lithographic apparatus of any of clauses 12 to 16, wherein the differential pressure measurement is between a pressure below a last lens element of the projection system and a pressure above the last lens element of the projection system.
19. The lithographic apparatus of any of clauses 12 to 18, wherein the controller is configured to identify up to ten exposure areas.
20. A computer program comprising computer readable instructions configured to cause a computer to carry out the method according to any of clauses 1 to 10.
21. A computer readable medium carrying the computer program according to clause 20.
22. The lithographic apparatus of any of clauses 12 to 16, wherein two or more pressure sensors are provided at a same side of a lens surface of the one or more lenses to measure a pressure difference over the lens surface.
23. The method of any of clauses 1 to 11, further calculating an additional image error caused by a change in refractive index of the fluid at the one or more lenses due to the change of differential pressure.
24. The method of any of clauses 1 to 5, wherein the change of the differential pressure is a change of differential pressure across a single side of a surface of the one or more lenses.
25. A method for controlling a projection system, the projection system comprising lens adjustment means, the method comprising:
receiving data of a first pressure in a compartment of the projection system and a second pressure in an environment at the projection system during a first exposure;
determining a pressure difference between the first and second pressure;
receiving data of lens adjustments based on a change in the pressure difference during the first exposure;
calculating a lens position error based on a time delay between the change and the lens adjustments provided by the lens adjustment means; and
determining a lens position for a second exposure based on the lens position error during the first exposure.

While specific embodiments of the invention have been described above, it will be appreciated that the invention may be practiced otherwise than as described. The descriptions above are intended to be illustrative, not limiting. Thus, it will be apparent to one skilled in the art that modifications may be made to the invention as described without departing from the scope of the claims set out below.

1-15. (canceled)

16. A method of controlling a projection system during exposure of a substrate by a lithographic apparatus, the method comprising:
obtaining a measurement signal of a change of a differential pressure across one or more lenses of the projection system;
calculating an imaging error caused by movement of one or more lens elements of the projection system due to the change of differential pressure during exposure;
calculating lens element adjustments, which compensate for the calculated imaging error;
applying the lens element adjustments;
identifying which exposure areas of the substrate were exposed during a delay between the change of differential pressure occurring and the lens element adjustments being applied; and
storing information of the identified exposure areas together with the calculated imaging error.

17. The method of claim 16, further comprising, during a subsequent exposure of the identified exposure areas of the substrate, applying lens element adjustments which apply an imaging error based on the calculated imaging error during exposure of the identified exposure areas.

18. The method of claim 17, wherein the imaging error that is applied during the subsequent exposure corresponds with the calculated imaging error.

19. The method of claim 16, wherein a time duration of the delay between the change of differential pressure occurring and the lens element adjustments being applied is determined, the determination taking into account a time duration between the change of differential pressure occurring and the measurement of the change of differential pressure being obtained.

20. The method of claim 16, wherein a time duration of the delay between the change of differential pressure occurring and the lens element adjustments being applied is determined, the determination taking into account a time duration during which the lens element adjustments are calculated.

21. The method of claim 16, wherein the measured differential pressure is between a pressure below a last lens element of the projection system and a pressure between a penultimate lens element and a preceding lens element of the projection system or between a pressure below a last lens element of the projection system and a pressure above the last lens element of the projection system.

22. The method of claim 16, further comprising using at least one differential pressure sensor to measure the differential pressure.

23. The method of claim 16, wherein more than one measured differential pressure is used.

24. The method of claim 19, wherein determining the time duration of the delay between the change of differential pressure occurring and the lens element adjustments being applied takes place during a calibration performed before exposure of the substrate has commenced.

25. The method of claim 16, further comprising identifying up to ten identified exposure areas.

26. A lithographic apparatus comprising:
a substrate table configured to hold a substrate;
a projection system configured to project a patterned radiation beam from a patterning device onto a substrate, the projection system comprising a plurality of lens elements;
one or more pressure sensors configured to obtain a differential pressure measurement across one or more lenses of the projection system;
a controller configured to calculate an imaging error caused by movement of one or more lens elements of the projection system due to a change of differential pressure occurring;
the controller further being configured to calculate lens element adjustments which compensate for the calculated imaging error; and
lens element adjusters configured to receive and apply the lens element adjustments;
wherein
the controller is further configured to determine which exposure areas of the substrate were exposed during a delay between the change of differential pressure occurring and the lens element adjustments being applied, and to store information identifying those exposure areas together with the calculated imaging error.

27. The lithographic apparatus of claim 26, wherein the controller is further configured to, during a subsequent exposure of the substrate, apply lens element adjustments which apply an imaging error based on the calculated imaging error during exposure of the identified exposure areas.

28. The lithographic apparatus of claim 26, wherein the imaging error that is applied during the subsequent exposure corresponds with the calculated imaging error.

29. The lithographic apparatus of any of claim 26, wherein the apparatus comprises at least one differential pressure sensor arranged to measure a pressure difference over at least one lens element.

30. The lithographic apparatus of claim 26, wherein the differential pressure measurement is between a pressure below a last lens element of the projection system and a pressure between a penultimate lens element and a preceding lens element of the projection system or between a pressure below a last lens element of the projection system and a pressure above the last lens element of the projection system.

31. The lithographic apparatus of claim 26, wherein the controller is configured to identify up to ten exposure areas.

32. The lithographic apparatus of claim 26, wherein two or more pressure sensors are provided at a same side of a lens surface of the one or more lenses to measure a pressure difference over the lens surface.

33. The method of claim 16, wherein the change of the differential pressure is a change of differential pressure across a single side of a surface of the one or more lenses.

34. A computer program product comprising non-transitory computer readable instructions configured to cause a computer to carry out the method according to claim 16.

35. A computer readable medium carrying the computer program product according to claim 34.
